(19) United States
(12) Patent Application Publication
(10) Pub. No.: US 2019/0312558 A1
(43) Pub. Date: Oct. 10, 2019

(54) AMPLIFIER CIRCUIT AND OPTICAL TRANSCEIVER

(71) Applicant: FUJITSU COMPONENT LIMITED, Tokyo (JP)

(72) Inventor: Hideki Oku, Tokyo (JP)

(21) Appl. No.: 16/376,271

(22) Filed: Apr. 5, 2019

(30) Foreign Application Priority Data
Apr. 10, 2018 (JP) 2018-075214

(51) Int. Cl. H03F 3/68; H03F 3/45; H04B 10/40

(52) U.S. Cl. CPC H03F 3/68; H03F 3/45188; H03F 3/45089; H04B 10/40; H03F 2203/45116; H03F 2200/165; H03F 2200/129; H03F 2203/45114; H03F 2200/171

(57) ABSTRACT

An amplifier circuit includes a first amplifier including input terminals and configured to amplify a signal, the signal being input into one of the input terminals; a second amplifier into which positive and negative outputs of the first amplifier are each input; a first low-pass filter into which outputs of the second amplifier are input; a high-pass filter into which outputs of the first amplifier are input; a second low-pass filter into which outputs of the high-pass filter are input; and a difference circuit configured to output a difference between outputs of the first low-pass filter and outputs of the second low-pass filter, wherein an output of the difference circuit is input into another one of the input terminals of the first amplifier.

### CROSS-REFERENCE TO RELATED APPLICATIONS

The present application is based on and claims priority to Japanese patent application No. 2018-075214 filed on Apr. 10, 2018, with the Japanese Patent Office, the entire contents of which are hereby incorporated by reference.

### BACKGROUND OF THE INVENTION

### 1. Field of the Invention

The disclosures herein relate to an amplifier circuit and an optical transceiver.

### 2. Description of the Related Art

In order to implement large-capacity information communication, high-speed optical communication systems have been widely used. In such an optical communication system, an optical transmitter and an optical receiver are used. In the optical receiver, a received optical signal is converted to an electric current signal by a photodiode, and the converted electric current signal is amplified and output.

A semiconductor laser is used as a light emitter of the optical transmitter, and an optical signal is generated by direct modulation of the semiconductor laser. When the optical signal is generated by direct modulation, an overshoot is present due to relaxation oscillation, and the waveform of the optical signal thus becomes asymmetrical in the amplitude direction. As a result, a binary value may be incorrectly determined, and incorrect data may be output.

In view of the above, there is a demand for an amplifier circuit that can output correct data even when an optical signal with an overshoot is received.

### RELATED-ART DOCUMENTS

### Patent Documents

### [Patent Document 1] Japanese Laid-open Patent Publication No. 2016-127496

### SUMMARY OF THE INVENTION

According to at least one embodiment, an amplifier circuit includes a first amplifier including input terminals and configured to amplify a signal, the signal being input into one of the input terminals; a second amplifier into which positive and negative outputs of the first amplifier are each input; a first low-pass filter into which outputs of the second amplifier are input; a high-pass filter into which outputs of the first amplifier are input; a second low-pass filter into which outputs of the high-pass filter are input; and a difference circuit configured to output a difference between outputs of the first low-pass filter and outputs of the second low-pass filter, wherein an output of the difference circuit is input into another one of the input terminals of the first amplifier.

Other objects and further features of the present invention will be apparent from the following detailed description when read in conjunction with the accompanying drawings.

### BRIEF DESCRIPTION OF THE DRAWINGS

FIG. 1 is a circuit diagram of an amplifier circuit;

FIG. 2 is a diagram (1) illustrating an input signal in the amplifier circuit;

FIG. 3 is a diagram illustrating an input signal detected by a photodiode;

FIG. 4 is a diagram (2) illustrating an input signal in the amplifier circuit;

FIG. 5 is a circuit diagram of an amplifier circuit according to a first embodiment;

FIGS. 6A through 6D are diagrams illustrating signal processing performed by the amplifier circuit according to the first embodiment;

FIGS. 7A and 7B are graphs for a low-pass filter and a high-pass filter;

FIGS. 8A and 8B are circuit diagrams of the low-pass filter and the high-pass filter;

FIG. 9 is a circuit diagram illustrating an example configuration of a linear amplifier;

FIG. 10 is a circuit diagram illustrating an example configuration of a limiting amplifier;

FIG. 11 is a circuit diagram illustrating an example configuration of an output stage;

FIG. 12 is a circuit diagram illustrating an example configuration of a differential amplifier;

FIG. 13 is a circuit diagram illustrating an example configuration of a limiting amplifier having an equalizer function;

FIG. 14 is a diagram illustrating optical transceivers according to the first embodiment; and

FIG. 15 is a circuit diagram of an amplifier circuit according to a second embodiment.

### DESCRIPTION OF THE PREFERRED EMBODIMENTS

According to an amplifier circuit disclosed herein, correct data can be output even when an optical signal with an overshoot is received.

In the following, embodiments of the present invention will be described with reference to the accompanying drawings. In the drawings, the same elements are denoted by the same reference numerals, and a duplicate description thereof will be omitted.

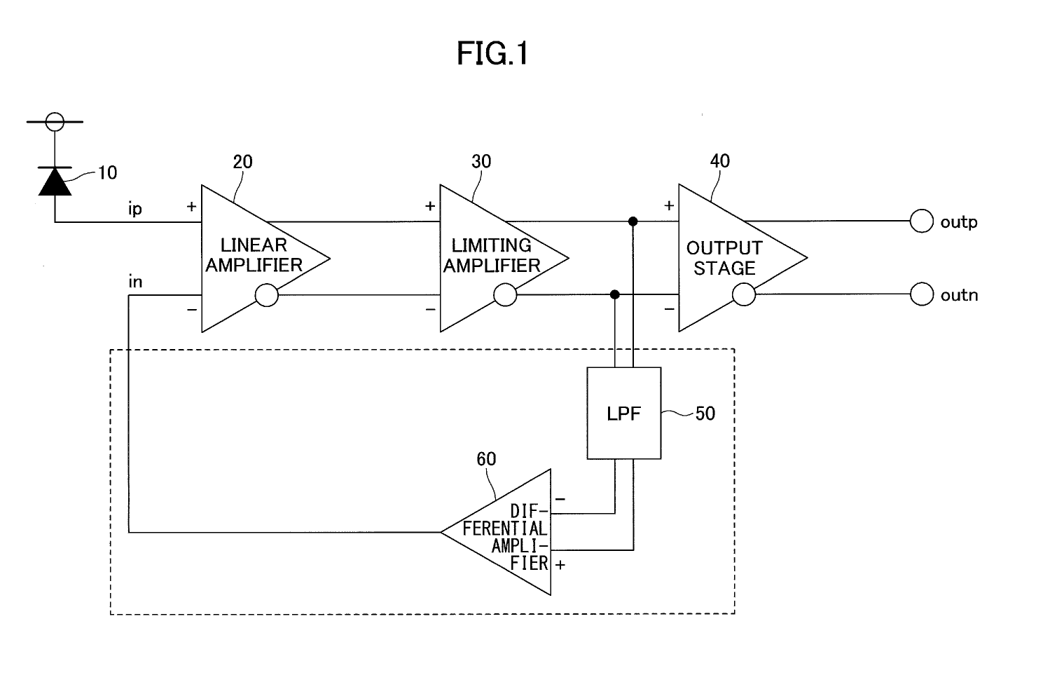

Incorrect binary determination which may happen when an optical signal with an overshoot is received will be described below. FIG. 1 is an amplifier circuit that amplifies an optical signal received by a photodiode.

The amplifier circuit illustrated in FIG. includes a linear amplifier 20, a limiting amplifier 30, an output stage 40, a low-pass filter (LPF) 50, and a differential amplifier 60. A photodiode 10 receives an optical signal. The cathode of the photodiode 10 is connected to a power supply potential, and the anode is connected to an input terminal (+) of the linear amplifier 20. An output of the differential amplifier 60 is input into an input terminal (−) of the linear amplifier 20.

An electric current signal ip output from the photodiode 10 is converted to a voltage signal by the linear amplifier 20, amplified by the limiting amplifier 30, and output as output signals outp and outn from the output stage 40. An output and an inverted output of the limiting amplifier 30 branch off to the LPF 50 where high frequency components are removed to output DC components, and are then input into the differential amplifier 60. An output of the differential amplifier 60 is an average value of positive and negative input signals of the differential amplifier 60, and is input into the input terminal (−) of the linear amplifier 20 as a signal “in”. In the amplifier circuit of FIG. 1, the DC component is feedback by using the LPF 50 and the differential amplifier 60. A part surrounded by a dash line including the LPF 50 and the differential amplifier 60 is a DC feedback circuit.

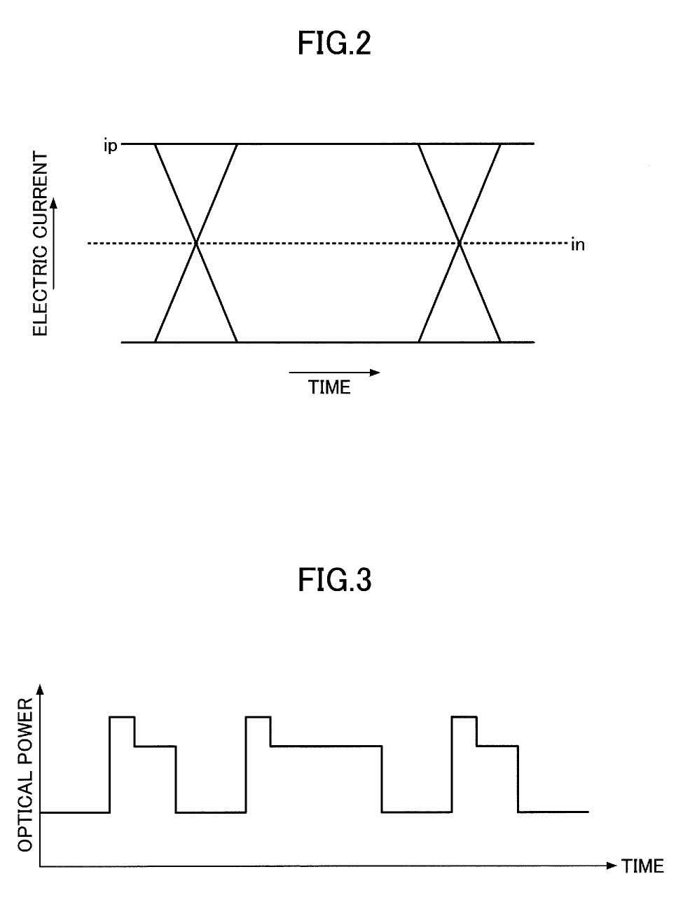

By applying DC feedback, an output of the differential amplifier 60 becomes the average of the signal ip input into the linear amplifier 20. In FIG. 2, the signal ip is indicated by a continuous line, and the output signal of the differential amplifier 60 is indicated by a dashed line. As illustrated in FIG. 2, when the waveform of the input signal, which is a binary signal, is symmetric in the amplitude direction, the value of the signal in output from the differential amplifier 60 is approximately between 0 and 1 of the binary signal. Accordingly, the signal in is an optimal threshold used to binarize the signal ip.

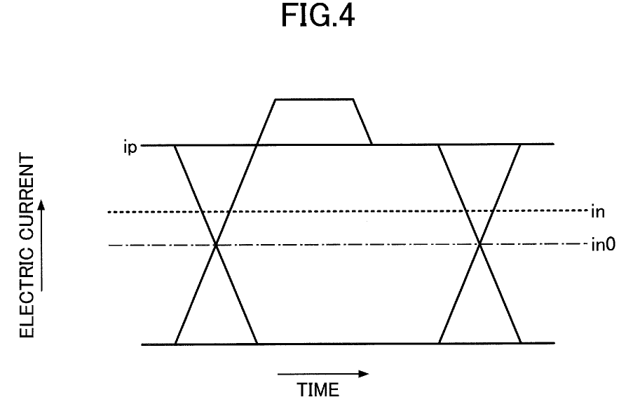

FIG. 4 illustrates an eye pattern of an input signal in the amplifier circuit of FIG. 1. An optical signal received by the photodiode 10 is a signal that is generated by direct modulation of a semiconductor laser of an optical transmitter. When the semiconductor laser is directly modulated, an overshoot occurs when an optical signal transitions from 0 to 1 due to relaxation oscillation. Therefore, an overshoot is present in an optical signal, and the waveform of the optical signal becomes asymmetric in the amplitude direction as illustrated in FIG. 3. Thus, the signal input into the input terminal (+) of the linear amplifier 20 would not have an ideal waveform as illustrated in FIG. 2 due to an overshoot as illustrated in FIG. 4. As a result, the signal in output from the differential amplifier 60 would be shifted from an optimal threshold in0. If the output signal of the differential amplifier 60 is shifted from the optimal threshold, binary values of an optical signal may be incorrectly determined.

### (Amplifier Circuit)

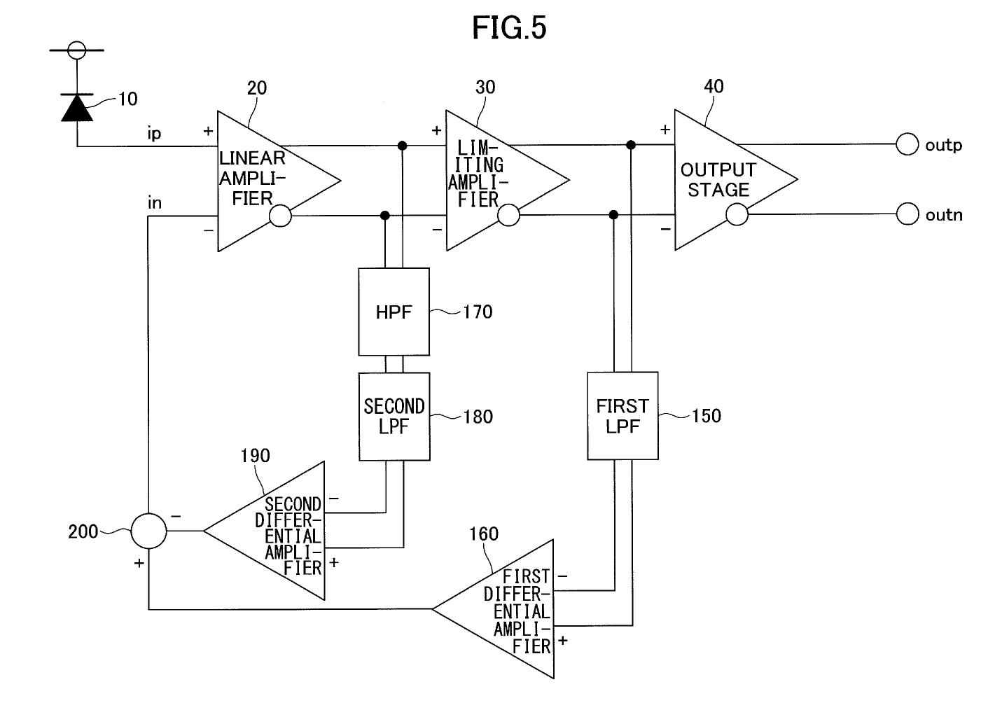

An amplifier circuit according to a first embodiment will be described with reference to FIG. 5. The amplifier circuit according to the first embodiment includes a linear amplifier 20, a limiting amplifier 30, an output stage 40, a first low-pass filter (LPF) 150, a first differential amplifier 160, a high-pass filter (HPF) 170, a second low-pass filter 180, a second differential amplifier 190, and a subtraction circuit 200. The cathode of the photodiode 10 is connected to a power supply potential, and the anode of the photodiode 10 is connected to an input terminal (+) of the linear amplifier 20.

An electric current output from the photodiode 10 is converted to a voltage signal by the linear amplifier 20, amplified by the limiting amplifier 30, and output from the output stage 40 as output signals outp and outn. An output and an inverted output of the limiting amplifier 30 are input into the first LPF 150 where high frequency components are removed to output DC components only, and are then input into the first differential amplifier 160. An output of the first differential amplifier 160 is input into an input terminal (+) of the subtraction circuit 200.

An output and an inverted output of the linear amplifier 20 branch off to the HPF 170, and are input into the second differential amplifier 190 through the second LPF 180. An output of the second differential amplifier 190 is input into an input terminal (−) of the subtraction circuit 200.

In the present embodiment, DC feedback is applied to the linear amplifier 20 by using the first LPF 150, the first differential amplifier 160, the HPF 170, the second LPF 180, and the second differential amplifier 190.

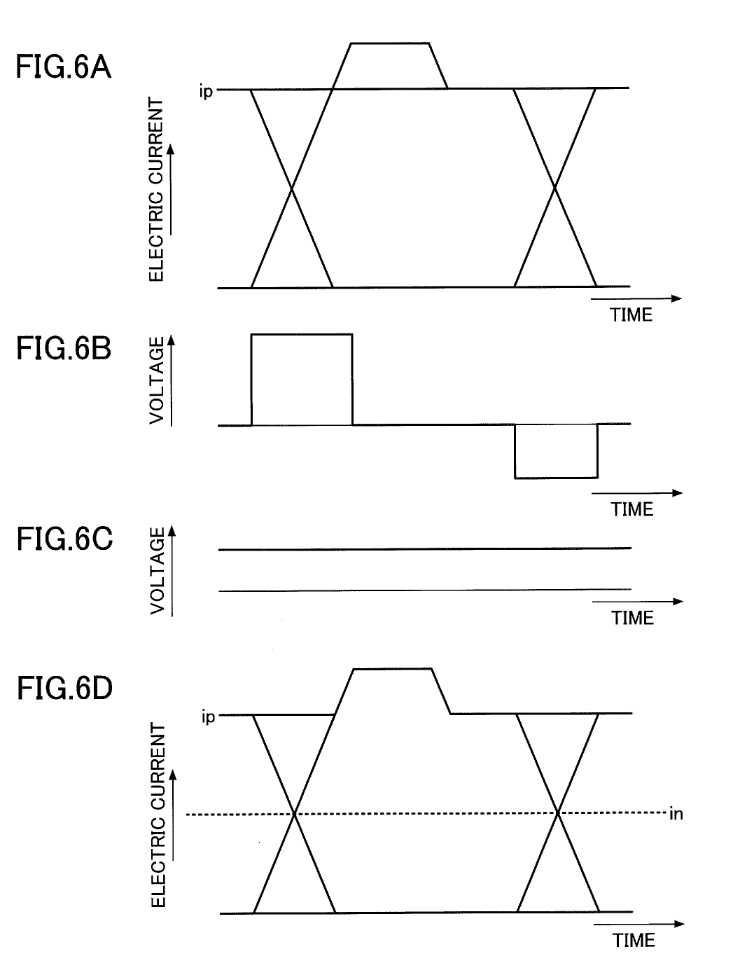

FIG. 6A illustrates an electric current signal ip with an overshoot input into the linear amplifier 20. In this example, low frequency components are removed by the HPF 170 and high frequency components are extracted as illustrated in FIG. 6B after the linear amplifier 20 converts the electric current signal ip to a voltage signal. An output of the linear amplifier 20 is differentiated by the HPF 170. Because the overshoot is present in the signal ip illustrated in FIG. 6A, the amplitude becomes large in accordance with the level of the overshoot at the rising edge of the waveform as illustrated in FIG. 6B. Subsequently, outputs of the HPF 170 are passed through the second LPF 180, such that DC components as illustrated in FIG. 6C are output. Next, the second differential amplifier 190 obtains a difference between two output signals of the second LPF 180, and input into the input terminal (−) of the subtraction circuit 200.

The subtraction circuit 200 outputs a signal obtained by subtracting an output of the second differential amplifier 190 from an output of the first differential amplifier 160. The output signal is input into the input terminal (−) of the linear amplifier 20 as a signal in.

Accordingly, the signal in to be input into the linear amplifier 20 can become closer to the optimal threshold of FIG. 6D by reducing an effect of an overshoot present in the signal ip. As a result, it is possible to prevent incorrect binary determination of an optical signal.

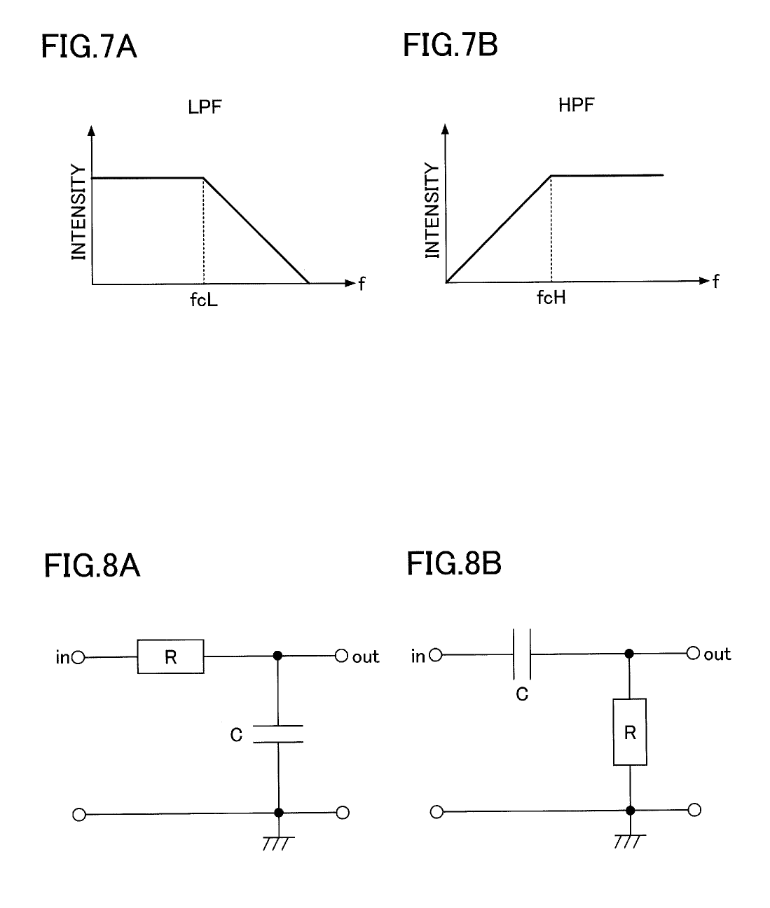

As illustrated in FIG. 7A, the first LPF 150 and the second LPF 180 remove frequency components higher than a cutoff frequency fcL. As illustrated in FIG. 7B, the HPF 170 removes frequency components lower than a cutoff frequency fcH. In a high-speed optical module in which the frequency of an optical signal input to the photodiode 10 is 25 Gbps or more, the cutoff frequency fcL of each of the first LPF 150 and the second LPF 180 is set to several hundreds of kHz, and the cutoff frequency fcH of the HPF 170 is set to approximately 1 GHz. A relationship between the cutoff frequency fcL versus the cutoff frequency fcH is fcL<fcH.

As illustrated in FIG. 8A, the first LPF 150 and the second LPF 180 each may be formed by a circuit in which a resistor R provided between an input (in) and an output (out) of a signal line and a capacitor C provided between a ground potential and the signal line are combined.

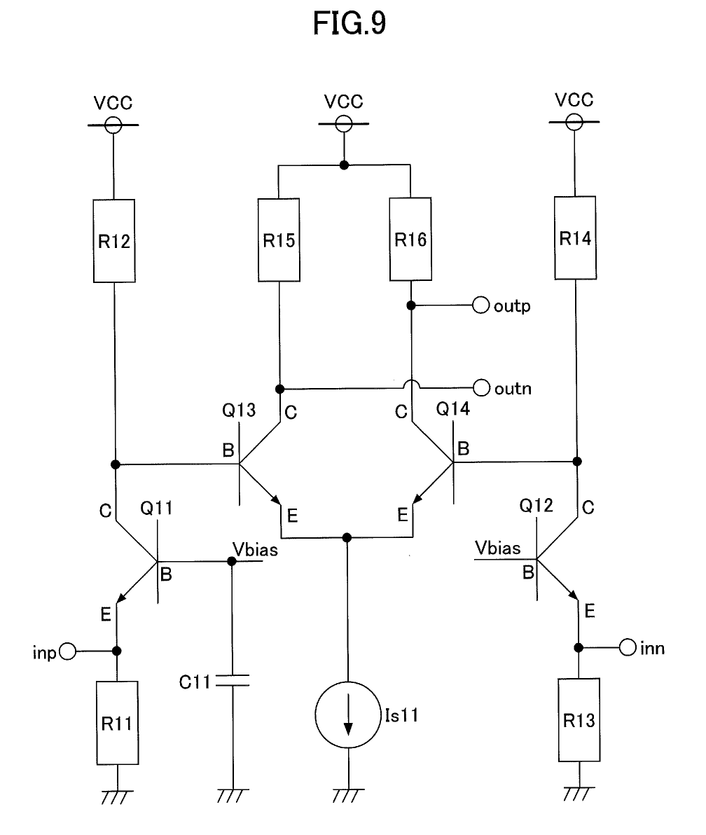

As illustrated in FIG. 9, the linear amplifier 20 may be formed by a circuit that includes a transistor Q11, a transistor Q12, a transistor Q13 and a transistor Q14. The transistors Q11 through Q14 are NPN (negative-positive-negative) transistors.

In the linear amplifier 20, a resistor R11, the transistor Q11, and a resistor R12 are connected in series. The resistor R11 is connected to an emitter E. of the transistor Q11 and an input terminal inp is connected between the resistor R11 and the emitter E. The resistor R12 is connected to a collector C of the transistor Q11 and a base B of the transistor Q13 is connected between the resistor R12 and the collector C. A resistor R15 is connected to a collector C of the transistor Q13 and an output terminal outn is connected between the resistor R15 and the collector C. The other end of the resistor R11 is grounded. The other end of the resistor R12 and the other end of the resistor R15 are each connected to a corresponding power supply potential VCC.

A resistor R13, the transistor Q12, and a resistor R14 are connected in series. The resistor R13 is connected to an emitter E of the transistor Q12 and an input terminal inn is connected between the resistor R13 and the emitter E. The resistor R14 is connected to a collector C of the transistor Q12 and a base B of the transistor Q14 is connected between the resistor R14 and the collector C. A resistor R16 is connected to a collector C of the transistor Q14 and an output terminal outp is connected between the resistor R16 and the collector C. The other end of the resistor R13 is grounded. The other end of the resistor R14 and the other end of the resistor R16 are each connected to a corresponding power supply potential VCC.

A capacitor C11 is provided between a base B of the transistor Q11 and a ground potential. Bias Voltage Vbias is applied to the base B of transistor Q11 and to the base B of the transistor Q12. The emitter E of the transistor Q13 and the emitter E of the transistor Q14 are both connected to an electric current source Is11.

An electric current signal ip input into the input terminal inp of the linear amplifier 20 is converted to a voltage signal and is output from the output terminal outn. A signal in input into the input terminal inn is converted to a voltage signal and is output from the output terminal outp.

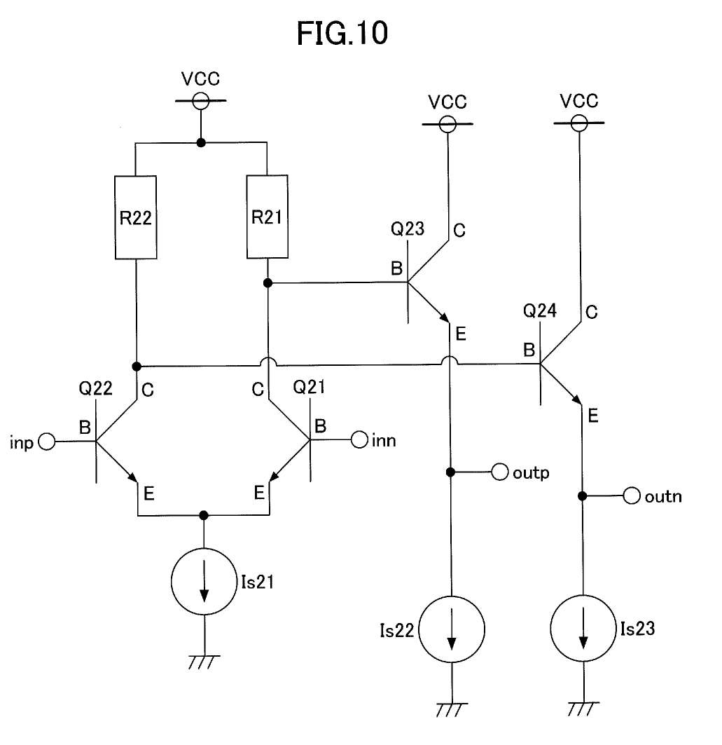

As illustrated in FIG. 10, the limiting amplifier 30 may be formed by a circuit that includes a transistor Q21, a transistor Q22, a transistor Q23, and a transistor Q24. Each of the transistors Q21 through Q24 are NPN transistors.

In the limiting amplifier 30, a series circuit of a resistor R21 and of the transistor Q21 and a series circuit of a resistor R22 and of the transistor Q22 are connected in parallel.

The resistor R21 is connected between a collector C of the transistor Q21 and a power supply potential VCC. The resistor R22 is connected between a collector C of the transistor Q22 and the power supply potential VCC. An emitter E of the transistor Q21 and an emitter E of the transistor Q22 are connected to an electric current source Is21. A base B of the transistor Q22 is connected to an input terminal inp. A base B of the transistor Q21 is connected to an input terminal inn. For example, the input terminal inp is connected to the output terminal outp of FIG. 9, and the input terminal inn is connected to the output terminal outn of FIG. 9.

The collector C of the transistor Q21 is connected to the base B of the transistor Q23. A collector C of the transistor Q23 is connected to a power supply potential VCC. An emitter E of the transistor Q23 is connected to an electric current source Is22 and is also connected to an output terminal outp.

The collector C of the transistor Q22 is connected to a base B of the transistor Q24. A collector C of the transistor Q24 is connected to a power supply potential VCC. An emitter E of the transistor Q24 is connected to an electric current source Is23 and is also connected to an output terminal outn.

A signal input into the input terminal inp of the limiting amplifier 30, and a signal input into the input terminal inn are differentially amplified by differential amplifier circuits having the transistor Q21 and the transistor Q22, amplified by a transistor Q23 and a transistor Q24, and output from the output terminal outn and the output terminal outp. The signals inverted with respect to the input signals are output from the limiting amplifier 30. In order to obtain required gain, multiple stages of transistors may be used.

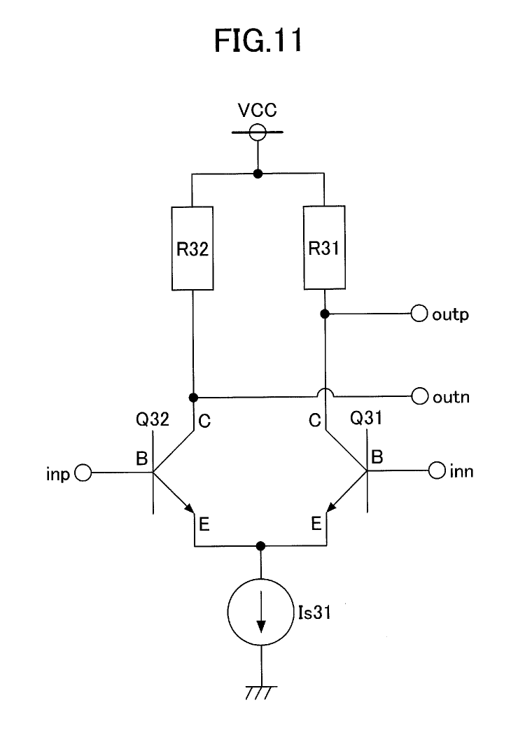

As illustrated in FIG. 11, the output stage 40 is formed by a circuit that includes a transistor Q31 and a transistor Q32 which are NPN transistors, for example.

In the output stage 40, a series circuit of a resistor R31 and of the transistor Q31 and a series circuit of a resistor R32 and of the transistor Q32 are connected in parallel.

A collector C of the transistor Q31 is connected to the resistor R31 and an output terminal outp is connected between the collector C and the resistor R31. The other end of the resistor R31 is connected to a power supply potential VCC. A collector C of the transistor Q32 is connected to the resistor R32 and an output terminal outn is connected between the collector C and the resistor R32. The other end of the resistor R32 is connected to the power supply potential VCC. An emitter E of the transistor Q31 and an emitter E of the transistor Q32 are connected to an electric current source Is31. A base B of the transistor Q32 is connected to an input terminal inp. A base B of the transistor Q31 is connected to an input terminal inn. The input terminal inp is connected to the output terminal outp of FIG. 10, and the input terminal inn is connected to the output terminal outn of FIG. 10.

A signal input into the input terminal inp of the output stage 40 and a signal input into the input terminal inn are output from the output terminal outn and the output terminal outp as inverted output signals outn and outp of FIG. 5.

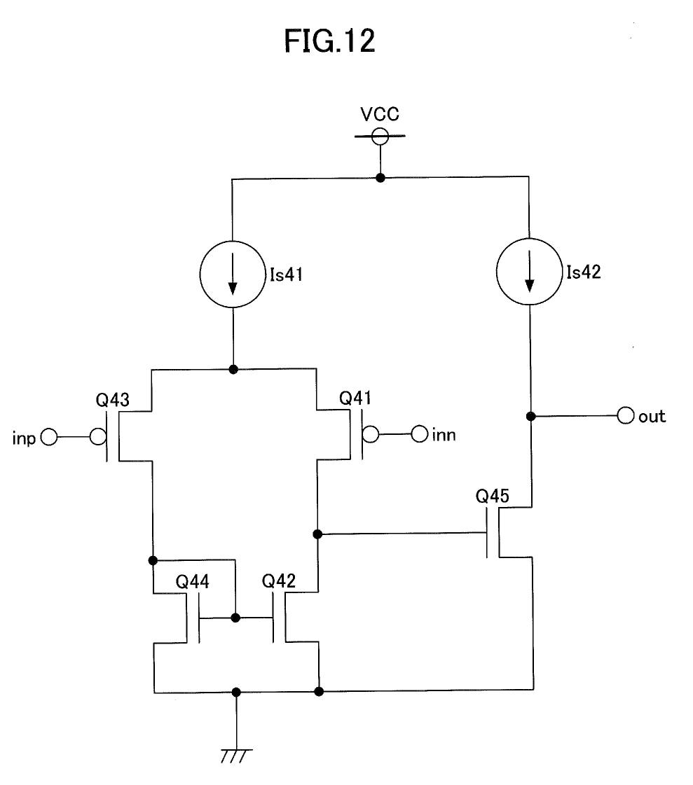

The first differential amplifier 160 and the second differential amplifier 190 will be described. Each of the first differential amplifier 160 and the second differential amplifier 190 may be an operational amplifier, and may be formed by a differential amplifier circuit as illustrated in FIG. 12. The differential amplifier circuit illustrated in FIG. 12 includes five field-effect transistors (FETs). In the differential amplifier circuit of FIG. 12, a series circuit of a FET Q41 and of a FET Q42 and a series circuit of a FET Q43 and of a FET Q44 are connected in parallel. An electric current source Is41 is connected to the above parallel circuit. A FET Q45 and an electric current source Is42 are connected in series.

A gate of the FET Q42 is connected to a gate of the FET Q44. The connecting part between the gates of the FETs Q42 and Q44 is connected to the connecting part between the FET Q43 and the FET Q44. The gate of the FET Q45 is connected between the FET Q41 and the FET Q42.

In the differential amplifier circuit, a gate of the FET Q41 is connected to an input terminal inn, and a gate of the FET Q43 is connected to an input terminal inp. An output terminal out is connected between the FET Q45 and an electric current source Is42.

In the differential amplifier circuit illustrated in FIG. 12, an input signal input into the input terminal inn and an input signal input into the input terminal inp are differentially amplified and output from an output terminal out.

### (Variation of Limiting Amplifier)

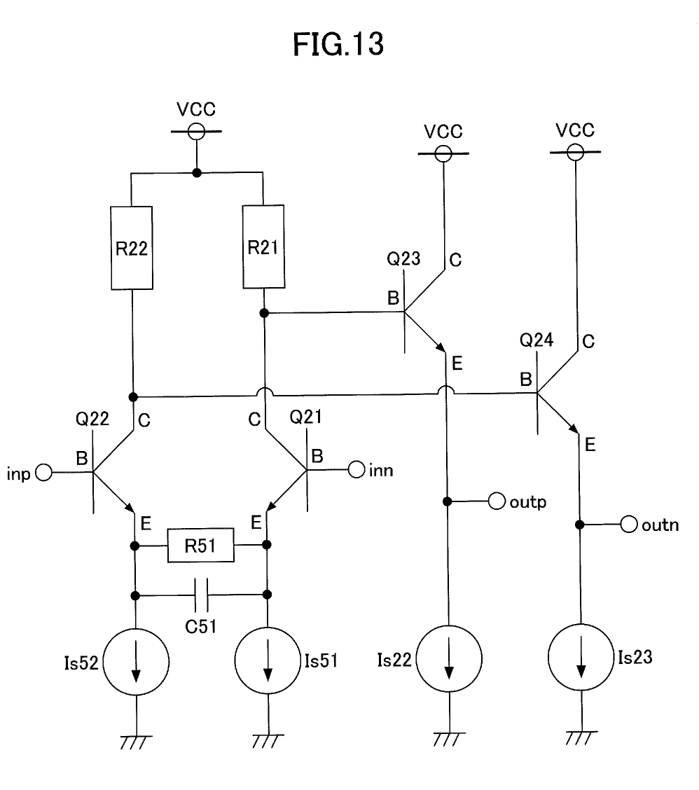

As illustrated in FIG. 13, a limiting amplifier having an equalizer function may be used. The equalizer function is a function for increasing the intensity of high frequency components of a signal.

In the limiting amplifier illustrated in FIG. 13, an emitter E of a transistor Q21 is connected to an electric current source Is51, and an emitter E of a transistor Q22 is connected to an electric current source Is52. A resistor R51 and a capacitor C51 are connected between the emitter E of the transistor Q21 and the emitter E of the transistor Q22. With the above configuration including the resistor R51 and the capacitor C51, it becomes possible to provide the limiting amplifier with the equalizer function.

### (Optical Transceiver)

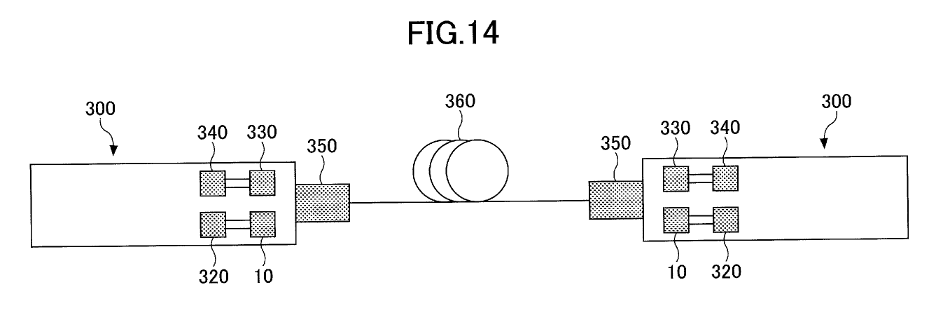

The amplifier circuit according to the embodiment may be used in optical transceivers. Optical transceivers 300 illustrated in FIG. 14 each include a photodiode 10, a transimpedance amplifier (TIA) 320, a light emitter 330, and a driver 340. The TIA 320 is formed by the amplifier circuit according to the embodiment. The light emitter 330 is a semiconductor laser such as a VCSEL. The driver 340 controls a driving current for a direct modulation.

Two optical transceivers 300 are connected by an optical fiber 360. Optical connectors 350 are provided at both ends of the optical fiber 360. The optical transceivers 300 are connected to the respective optical connectors 350. With the above configuration, the two optical transceivers 300 perform optical communication via the optical fiber 360. An optical signal generated by a light emitter 330 of one of the optical transceivers 300 is received by a photodiode 10 of the other optical transceiver 300, and is output as an electric current via a corresponding TIA 320.

### Second Embodiment

An amplifier circuit according to a second embodiment will be described. In the second embodiment, the first differential amplifier 160, the second differential amplifier 190, and the subtraction circuit 200 according to the first embodiment are combined into one unit.

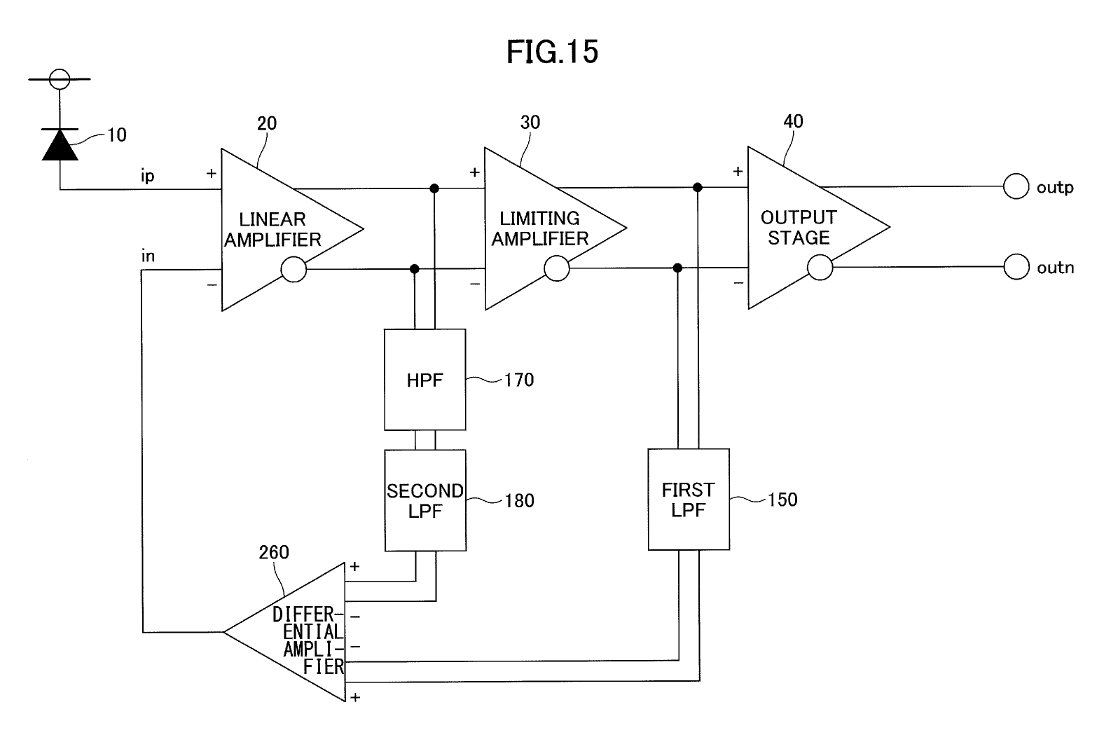

A differential amplifier 260 having four input terminals is provided as illustrated in FIG. 15. Outputs of the first LPF 150 are input into a first input terminal (+) and a first input terminal (−) of the differential amplifier 260, and outputs of the second LPF 180 are input into a second input terminal (+) and a second input terminal (−) of the differential amplifier 260. The outputs of the second LPF 180 are inverted and input into the second input terminal (+) and the second input terminal (−) of the differential amplifier 260.

Details other than the above are the same as those in the first embodiment.

Although the embodiments of the present invention have been specifically described above, the present invention is not limited to the above-described embodiments. Various modifications and variations may be made without departing from the scope of the present invention.

What is claimed is:

1. An amplifier circuit comprising:
a first amplifier including input terminals and configured to amplify a signal, the signal being input into one of the input terminals;
a second amplifier into which positive and negative outputs of the first amplifier are each input;
a first low-pass filter into which outputs of the second amplifier are input;
a high-pass filter into which outputs of the first amplifier are input;
a second low-pass filter into which outputs of the high-pass filter are input; and
a difference circuit configured to output a difference between outputs of the first low-pass filter and outputs of the second low-pass filter,
wherein an output of the difference circuit is input into another one of the input terminals of the first amplifier.

2. The amplifier circuit according to claim 1, wherein the difference circuit includes
a first differential amplifier into which the outputs of the first low-pass filter are input; and
a second differential amplifier into which the outputs of the second low-pass filter are input, and
wherein the difference circuit outputs a difference between an output of the first differential amplifier and an output of the second differential amplifier.

3. The amplifier circuit according to claim 1, wherein the difference circuit is a differential amplifier.

4. The amplifier circuit according to claim 1, wherein the second amplifier includes an equalizer function.
